(19) United States
(12) Patent Application Publication
(10) Pub. No.: US 2009/0166788 A1
(43) Pub. Date: Jul. 2, 2009

(54) IMAGE SENSOR AND METHOD FOR MANUFACTURING THE SAME

(76) Inventor: Gun-Hyuk Lim, Songpa-gu (KR)

Correspondence Address: SHERR & VAUGHN, PLLC, 620 HERNDON PARKWAY, SUITE 200, HERNDON, VA, 20170, US

(21) Appl. No.: 12/344,440

(22) Filed: Dec. 26, 2008

(30) Foreign Application Priority Data
Dec. 27, 2007 (KR) 10-2007-0139214

(51) Int. Cl. H01L 31/0224; H01L 31/18

(52) U.S. Cl. 257/459; 257/462; 438/98; 257/E31.125; 257/E21.002

(57) ABSTRACT

Provided is an image sensor and a method for manufacturing the same. In the image sensor, a semiconductor substrate has a readout circuitry formed thereon. An interlayer insulating layer including a lower metal line is on the semiconductor substrate, the lower metal line being electrically connected with the readout circuitry. A buffer insulating layer is on the interlayer insulating layer. A lower electrode penetrates the buffer insulating layer to be connected with the lower metal line. A crystalline semiconductor layer is on the buffer insulating layer, the crystalline semiconductor layer being partially connected with the lower electrode. A photodiode is in the crystalline semiconductor layer.

The present application claims priority under 35 U.S.C. 119 to Korean Patent Application No. 10-2007-0139214 (filed on Dec. 27, 2007), which is hereby incorporated by reference in its entirety.

### BACKGROUND

An image sensor is a semiconductor device that converts an optical image to an electric signal. Image sensors are generally classified into charge coupled device (CCD) image sensor and complementary metal oxide silicon (CMOS) image sensor (CIS). In one related image sensor, a photodiode is formed in a substrate using ion implantation. As the size of a photodiode is reduced more and more for the purpose of increasing the number of pixels without an increase in a chip size, the area of a light receiving portion is reduced, resulting in a reduction of image quality.

Also, since a stack height does not shrink as much as the reduction in the area of the light receiving portion, the number of photons incident to the light receiving portion is also reduced due to diffraction of light (known as the Airy disk or Airy pattern). As an alternative to address these issues, attempts of forming a photodiode using amorphous silicon (Si) have been made as well as attempts of forming a readout circuitry in a Si substrate using a method such as wafer-to-wafer bonding and forming a photodiode on the readout circuitry (referred to as a “three-dimensional (3D) image sensor”). The photodiode is connected with the readout circuitry through a metal line. However, while the wafer-to-wafer bonding is performed a defect may be caused in the photodiode, so that dark current may be generated.

### SUMMARY

Embodiments relate to an image sensor and a method for manufacturing the same that can increase the fill factor and decrease the generation of a defect in a bonding surface. Embodiments relate to an image sensor that includes a semiconductor substrate having a readout circuitry formed thereon; an interlayer insulating layer including a lower metal line on the semiconductor substrate, the lower metal line being electrically connected with the readout circuitry; a buffer insulating layer on the interlayer insulating layer; a lower electrode penetrating the buffer insulating layer to be connected with the lower metal line; a crystalline semiconductor layer on the buffer insulating layer, the crystalline semiconductor layer being partially connected with the lower electrode; and a photodiode in the crystalline semiconductor layer.

Embodiments also relate to a method for manufacturing an image sensor that includes forming a readout circuitry on a semiconductor substrate; forming an interlayer insulating layer including a lower metal line on the semiconductor substrate such that the lower metal line is electrically connected with the readout circuitry; forming a crystalline semiconductor layer on a carrier substrate; forming a buffer insulating layer on the crystalline semiconductor layer; forming a photodiode in the crystalline semiconductor layer; forming a lower electrode penetrating the buffer insulating layer to be connected with the photodiode; bonding the interlayer insulating layer to the buffer insulating layer of the carrier substrate such that the lower metal line is connected with the lower electrode; and removing the carrier substrate such that the photodiode on the semiconductor substrate is exposed, wherein the lower electrode comprises an electrode section having a first width, and a via contact extending from the electrode section and having a second width narrower than the first width, some of the via contact being inserted in the crystalline semiconductor layer, and the electrode section of the lower electrode is connected with the lower metal line.

### DRAWINGS

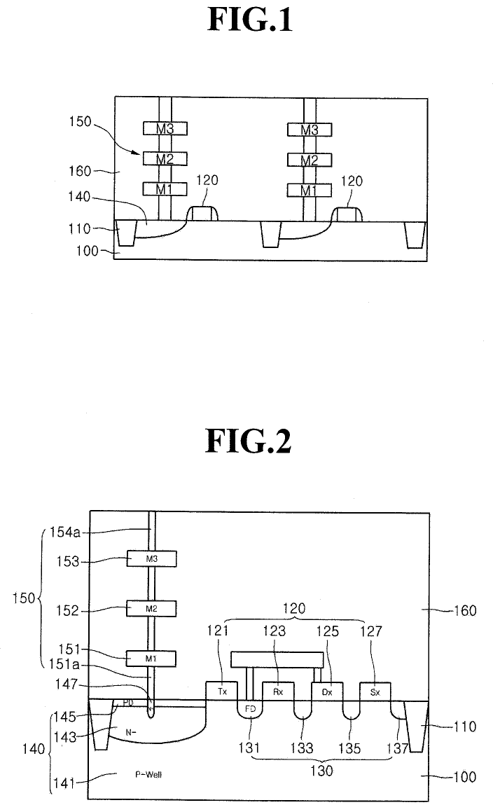

Example FIGS. 1 to 9 are cross-sectional views illustrating a method for manufacturing an image sensor according to embodiments.

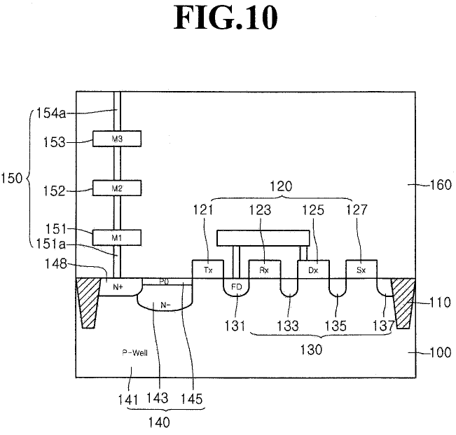

Example FIG. 10 is a partial detailed view of an image sensor according to embodiments.

### DESCRIPTION

Example FIG. 9 is a sectional view of an image sensor according to embodiments that includes a semiconductor substrate 100 having a readout circuitry 120 formed thereon; an interlayer insulating layer 160 including a lower metal line 150 on, or over, the semiconductor substrate 100, wherein the lower metal line 150 may be electrically connected with the readout circuitry 120. The readout circuitry 120 may also include a buffer insulating layer 210 on, or over, the interlayer insulating layer 160; a lower electrode 240 penetrating the buffer insulating layer 210 to be connected with the lower metal line 150; a crystalline semiconductor layer 200 disposed on, or over, the buffer insulating layer 210, the crystalline semiconductor layer 200 being partially connected with the lower electrode 240; and a photodiode 220 in the crystalline semiconductor layer 200.

The photodiode 220 of FIG. 1 is only an example and other photodiodes are contemplated such as, for example, the photodiode 220 may have a coupling structure of a photodiode and a photogate. Also, in the above description, the photodiode 220 is formed in the crystalline semiconductor layer 200, however the photodiode 220 may alternatively be formed in an amorphous silicon layer, for example.

The lower electrode 240 may include an electrode section 241 connected with the lower metal line 150 and having a first width D1; and a via contact 242 extending upward from the electrode section 241 and having a second width D2 narrower than the first width D1, some of the via contact 242 extending into the crystalline semiconductor layer 200. The readout circuitry 120 of the semiconductor substrate 100 may include an electrical junction region 140 formed in the semiconductor substrate 100.

A method for manufacturing an image sensor according to embodiments is provided with reference to example FIGS. 1 to 9. Referring to example FIG. 1, a readout circuitry 120 may be formed on, or over, a semiconductor substrate 100. Also, a lower metal line 150 connected with the readout circuitry 120 may be formed on, or over, the semiconductor substrate 100. Example FIG. 2 is a detailed view of the semiconductor substrate 100 on which the readout circuitry 120 and the lower metal line 150 shown in FIG. 1 are formed.

First, as shown in FIG. 2, the semiconductor substrate 100 having the lower metal line 150 and the readout circuitry 120 formed thereon is prepared. For example, an active region may be defined by forming a device isolation layer 110 in a second conductive type semiconductor substrate 100, and then the readout circuitry 120 including a transistor may be formed in the active region. The readout circuitry 120 may include, for example, a transfer transistor (Tx) 121, a reset transistor (Rx) 123, a drive transistor (Dx) 125, and a select transistor (Sx) 127. Thereafter, an ion implantation region 130 including a floating diffusion region (FD) 131, i.e., source/drain regions 133, 135, 137 for each transistor may be formed.

The forming of the readout circuitry 120 in the semiconductor substrate 100 may include forming an electrical junction region 140 in the semiconductor substrate 100 and forming a first conductive type connection region 147 connected with the lower metal line 150 on, or over, the electrical junction region 140. For example, the electrical junction region 140 may be a PN junction 140 or may also, for example include a first conductive type ion implantation layer 143 formed on a second conductive well 141 or a second conductive type epitaxial (epi) layer, and a second conductive type ion implantation layer 145 formed on the first conductive type ion implantation layer 143. For example, the PN junction 140 may be P0/N−/P− junction (reference numerals 145/143/141) as shown in example FIG. 2. The semiconductor substrate may also be doped with a second conductive type impurity, but not necessarily.

According to embodiments, it may be possible to fully dump photo charges by designing the image sensor such that there exists a potential difference between source and drain of the transfer transistor (Tx). By doing so, the photo charges generated in the photodiode can be dumped into the floating diffusion region, thereby enhancing the sensitivity of an output image. In other words, by forming the electrical junction region 140 in the semiconductor substrate 100 having the readout circuitry 120 formed thereon and thus generating a potential difference between source and drain of the transfer transistor (Tx), it may be possible to fully dump the photo charges.

Unlike the floating diffusion (FD) 131 node that may be an N+ junction, the electrical junction region 140 may not fully receive an applied voltage but, rather, may be pinched off at a constant voltage. This voltage is called the “pinning voltage” and is affected by doping concentrations of P0 145 and P− 143.

The electrons generated in the photodiode 220 (see example FIG. 9) move to the PNP junction 140, and when the transfer transistor (Tx) 121 is turned on, they are transferred to the FD 131 node and converted to a voltage. Since a maximum voltage value of the P0/N−/P− junction 140 becomes the pinning voltage and a maximum voltage value of the FD 131 node becomes V_{dd}-Rx Vₜₕ, the electrons generated in the photodiode 220 on a chip can be fully dumped into the FD 131 node without charge sharing due to a potential difference between source and drain of the transfer transistor (Tx) 131.

One reason that a P0/N−/Pwell junction, rather than a N+/Pwell junction, is formed in the semiconductor substrate 100 is because in a 4-Tr APS Reset operation, a positive (+) voltage is applied to N− 143 of the P0/N−/Pwell junction and ground voltage is applied to P0 145 and Pwell 141. Thus, under a voltage of more than a constant voltage, P0/N−/Pwell double junction is pinched off like in the BJT structure. As mentioned before, this is called the “pinning voltage”. Accordingly, a potential difference between source and drain of the transfer transistor (Tx) 121 is generated and, thus when the transfer transistor (Tx) is turned on/off, a charge sharing phenomenon can be prevented. Accordingly, unlike in the related photodiode that is connected to the N+ junction, the embodiments avoid the saturation and sensitivity from being lowered.

Next, in accordance with embodiments, the first conductive type connection region 147 may be formed between the photodiode and the readout circuitry to help smooth movement of photo charges, thereby minimizing a source of dark current and limiting, or preventing, the saturation and sensitivity from being lowered. Accordingly, in embodiments, the first conductive connection region 147 may be formed for an ohmic contact in a surface of the P0/N−/P− junction 140. The N+ region 147 may be formed so as to penetrate the P0 145 and contact the N− 143.

To minimize the first conductive type connection region 147 acting as a leakage source, the width of the first conductive type connection region 147 may be minimized. For this purpose, a first metal contact 151a may be first etched and a plug may then be implanted. Other techniques are contemplated as well such as, for example, the first conductive type connection region 147 may be formed by first forming an ion implantation pattern and using the formed ion implantation pattern as an ion implantation mask. Doing so may minimize a dark signal and form the ohmic contact smoothly, N+ doping is locally performed to the contact portion similar to that described earlier. If, in contrast, N+ doping is performed to the entire region of source of the transfer transistor (Tx), a dark signal may be increased due to Si surface dangling bonds.

Next, an interlayer insulating layer 160 may be formed on, or over, the semiconductor substrate 100, and a lower metal line 150 may then be formed. As one example, the lower metal line 150 may include a first metal contact 151a, a first metal (M1) 151, a second metal (M2) 152, a third metal (M3) 153 and a fourth metal contact 154, but other structures are contemplated as well.

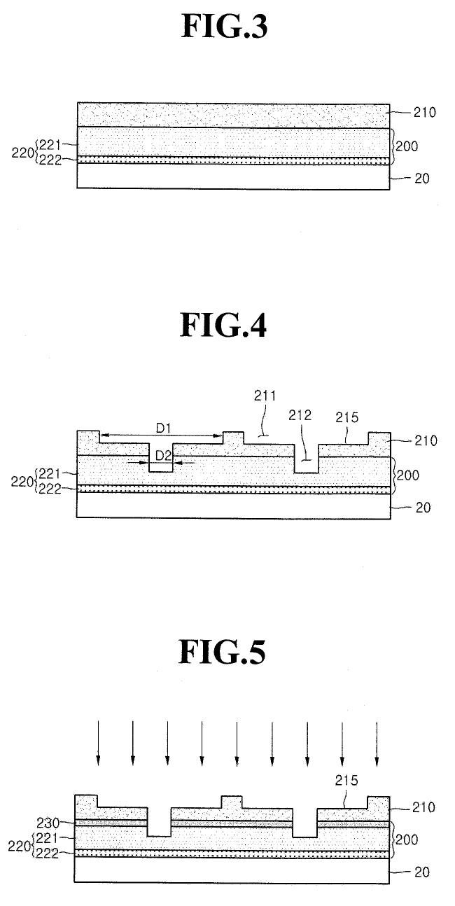

Referring to example FIG. 3, a carrier substrate 20 including a crystalline semiconductor layer 200 is prepared. The carrier substrate 20 may be a single crystalline or polycrystalline silicon substrate doped with a p-type or n-type impurity. The crystalline semiconductor layer 200 may be an upper region of the carrier substrate 20. Next, a buffer insulating layer 210 may be formed on, or over, the crystalline semiconductor layer 200. For example, the buffer insulating layer 210 may be formed of oxide. The buffer insulating layer 210 may be formed on the crystalline semiconductor layer 200 by using a thermal oxidation or CVD. A photodiode 220 may then be formed inside the crystalline semiconductor layer 200. The photodiode 220 includes a first conductive region 221 and a second conductive region 222.

The first conductive region 221 may be formed at an inner upper region of the crystalline semiconductor layer 200. For example, the first conductive region 221 may be formed by implanting an n-type impurity ion. The second conductive region 222 may be formed at an inner lower region of the crystalline semiconductor layer 200. For example, the second conductive region 222 may be formed by implanting a p-type impurity ion. Since the second conductive region 222 is formed under the first conductive region 221, the photodiode 220 may have a PN junction structure. The first conductive region 221 may be formed thicker than the second conductive region 222. By doing so, it may be advantageous to generate photo charges. Alternatively, the photodiode 220 may be formed before the buffer insulating layer 210 is formed.

Referring to example FIG. 4, a via trench 215 penetrating the buffer insulating layer 210 may be formed. The via trench 215 may be formed corresponding to the lower metal line 120. That is, the via trench 215 may be formed per unit pixel. The via trench 215 may be formed by a damascene process. The via trench 215 may be formed by forming a shallow trench at an upper portion of the buffer insulating layer 210 and then forming a via hole 212 connected with the trench 211 and penetrating the buffer insulating layer 210 to expose the photodiode 220. Alternatively, the via trench 215 may be formed by first forming the via hole 212 and then forming the trench 211. The trench 211 may have a first width D1 and the via hole 212 may have a second width D2 narrower than the first width D1. The via hole 212 may expose the first conductive region 221 of the photodiode 220. That is, by removing some of the crystalline semiconductor layer 200 during the forming of the via hole 212, an inside of the first conductive region 221 of the photodiode 220 may be selectively exposed. The width of the trench 211 may be formed as wide as possible such that an interval between the trenches 211 is minimal.

Referring to example FIG. 5, an ohmic contact layer 230 may be added on, or over, the semiconductor layer 200. That is, the ohmic contact layer 230 may be formed on, or over, the first conductive region 221. For example, the ohmic contact layer 230 may be formed by implanting an n-type impurity ion at a high concentration. When the ohmic contact layer 230 is formed at one side of the first conductive region 221, a contact resistance between the photodiode 220 and the lower metal line 120 can be decreased. Alternatively, forming the ohmic contact layer 230 in this manner may be omitted.

As described above, since the photodiode 220 and the ohmic contact layer 230 may be formed inside the crystalline semiconductor layer 200 by implanting impurity ions into the crystalline semiconductor layer 200, generation of a defect in the photodiode and generation of dark current can be reduced or prevented. Alternatively, the ohmic contact layer 230 may be formed after the photodiode 220 is formed.

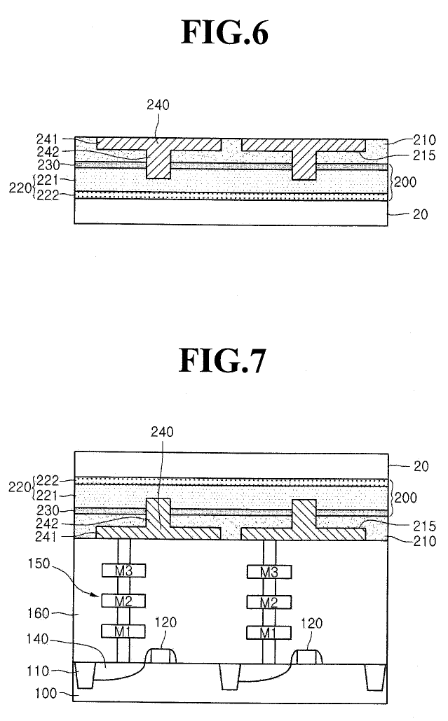

Referring to example FIG. 6, a lower electrode 240 may be formed inside the via trench 215 of the buffer insulating layer 210. The lower electrode 240 may be formed by forming a metal layer inside the via trench 215 and planarizing the formed metal layer. For example, the lower electrode 240 may be formed by depositing an appropriate material using a PVD. Such a material may, for example, be one or a combination of Cr, Ti, TiN, Ta, TaN, Al, Cu and W Thereafter, a chemical mechanical polishing (CMP) process may be performed until an upper surface of the lower electrode 240 and an upper surface of the buffer insulating layer 210 have substantially the same height.

The lower electrode 240 may be formed per unit pixel so as to correspond to the lower metal line 150. To assist in distinguishing the different portions of the lower electrode 240, the portion of the lower electrode 240 formed in the trench 211 is referred to as “electrode section” 241 and the portion of the lower electrode 240 formed in the via hole 212 is referred to as the “via contact” 242. The electrode section 241 may have a first width D1 and the via contact 242 may have a second width which is less than the first width D1. The electrode section 241 is formed inside the trench 211 and the electrode section 241 may be exposed together with the buffer insulating layer 210. The electrode section 241 may be formed so as to be spaced apart by a minimum interval from the neighboring electrode section 241. Accordingly, since the electrode section 241 may be formed with a wide area, the electrode section 241 can gather as many photons generated in the photodiode 220 as possible.

Since some of the via contact 242 may extend to an inside of the first conductive region 221 of the photodiode 220, it is possible to separate the photodiode 220 per unit pixel.

Referring to example FIG. 7, the semiconductor substrate 100 including the lower metal line 150 may be coupled with the carrier substrate 20 including the crystalline semiconductor layer 200. The semiconductor substrate 100 and the carrier substrate 20 may be coupled by a bonding process. For example, the carrier substrate 20 may be positioned over the interlayer insulating layer 160 of the semiconductor substrate 100 such that an exposed surface of the buffer insulating layer 210 of the carrier substrate 20 contacts the interlayer insulating layer 160 of the semiconductor substrate 100, and then a bonding process is performed. In particular, the bonding process may be performed such that the lower metal line 150 of the interlayer insulating layer 160 is aligned with the electrode section 241 of the lower electrode 240 of the buffer insulating layer 210. By doing so, the crystalline semiconductor layer 200 including the photodiode 220 can be correctly coupled on the semiconductor substrate 100. Accordingly, the semiconductor substrate 100 and the photodiode 220 are made in a vertical integration, thereby enhancing the fill factor.

Also, the lower metal line 150 and the lower electrode 240 may be independently connected per unit pixel. In particular, since the electrode section 241 of the lower electrode 240 has the first width D1, an alignment between the lower electrode 240 and the lower metal line 150 can be easily performed. Accordingly, the photons generated in the photodiode 220 can be delivered to the lower metal line 150 through the lower electrode 240 in each pixel.

Because the buffer insulating layer 210 protects the surface of the crystalline semiconductor substrate 100 having the photodiode 220 formed thereon, the stress applied in the bonding process may be reduced. Since the buffer insulating layer 210 under the photodiode 220 may directly contact the interlayer insulating layer 160 of the semiconductor substrate 100, the buffer insulating layer 210 may act as a buffer layer in the bonding process to decrease a leakage component. Also, when the buffer insulating layer 210 is left on the crystalline semiconductor layer 200 instead of being removed, the manufacturing process can be simplified. Furthermore, any potential etch damage of the photodiode 220 that may be caused when removing the buffer insulating layer 210 can be avoided, thereby enhancing the device reliability.

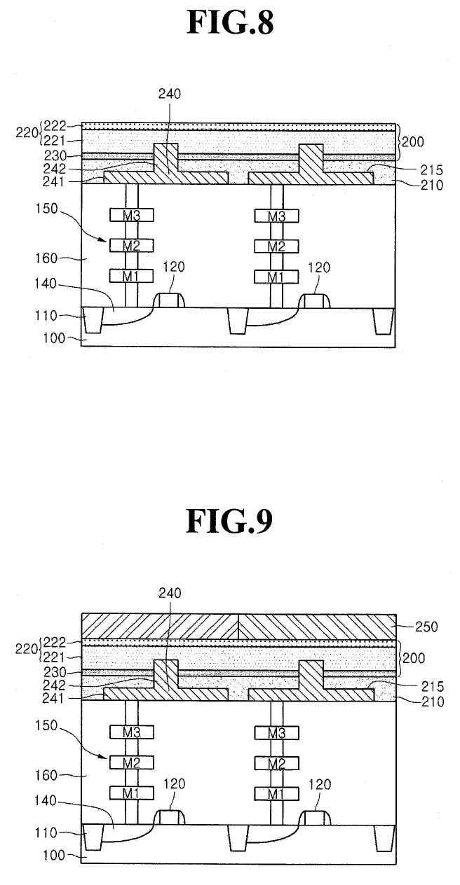

Referring to example FIG. 8, the carrier substrate 20 may be removed such that the crystalline semiconductor layer 200 is left on, or over, the semiconductor substrate 100. After the carrier substrate 20 is removed, the buffer insulating layer 210 and the crystalline semiconductor layer 200 are left on the semiconductor substrate 100. Because the buffer insulating layer 210 including the lower electrode 240 and the crystalline semiconductor layer 200 including the photodiode 220 may be left on the semiconductor substrate 100, the semiconductor substrate 100 and the photodiode 220 can achieve vertical integration. Although not shown in the drawings, an upper electrode used as a ground electrode may be further formed on the photodiode 220.

Referring to example FIG. 9, a color filter 250 may be formed on, or over, the crystalline semiconductor layer 200. The color filter 250 may be formed per unit pixel to filter colors from incident light. Alternatively, a micro lens may be further formed on the color filter 250.

According to embodiments for manufacturing an image sensor, the semiconductor substrate including the lower metal line may be coupled with the crystalline semiconductor layer including the photodiode to achieve a vertical integration, thereby enhancing the fill factor of the photodiode. Furthermore, an additional on-chip circuitry, which can be integrated can increase the performance of the image sensor, achieve device miniaturization and reduce manufacturing costs. Because a vertical type photodiode is employed that may be formed by implanting impurity ions into a single crystal substrate, generation of defects in the photodiode can be reduced or prevented. Also, because the buffer insulating layer is formed on the crystalline semiconductor layer having the photodiode formed therein, stress that may occur in the bonding process may be reduced.

Example FIG. 10, according to embodiments, depicts a partial detailed view of an image sensor that includes a semiconductor substrate 100 having a readout circuitry 120 formed thereon; a metal line 150 formed on, or over, the semiconductor substrate 100 so as to be electrically connected with the metal line 150; and a photodiode electrically connected with the metal line 150 and formed on a crystalline semiconductor layer over the semiconductor substrate 100.

As described previously, because the electrode section 241 of the lower electrode 240 has the first width D1, the electrode section 241 can be easily aligned with the lower metal line 150. Accordingly, the photons generated in the photodiode 220 can be delivered to the lower metal line 150 through the lower electrode 240 in each pixel. Also, because the buffer insulating layer 210 protects the surface of the crystalline semiconductor substrate 100 having the photodiode 220 formed thereon, it is possible to reduce stresses that may be caused in the bonding process.

In FIG. 10, however, a first conductive type connection region 148 may be formed at one side of the electrical junction region 140. Accordingly, the N+ connection region 148 for an ohmic contact may be formed in the P0/N−/P− junction 140. At this time, the N+ connection region 148 and a contact 151a may act as a leakage source. This is because in operation, a reverse bias is applied to the P0/N−/P− junction 140 and an electric field is generated in the surface of the Si substrate. Under the generated electric field, a crystal defect generated in forming the contact may act as a leakage source. Also, in the case where the N+ connection region 148 is formed on a surface of the P0/N−/P− junction 140, an additional electric field is generated by the N+/P0 junction 148/145, which may also act as a leakage source.

Accordingly, FIG. 10 allows for a layout in which a doping into the P0 layer may not be performed. First a contact plug 151a may formed in an active region including the N+ connection region 148, and the first contact plug 151a may be connected to the N− junction 143. As a result, an electric field may not be generated in the surface of the silicon substrate, which can contribute to a decrease in the dark current of the 3-D integrated CIS.

It will be obvious and apparent to those skilled in the art that various modifications and variations can be made in the embodiments disclosed. Thus, it is intended that the disclosed embodiments cover the obvious and apparent the modifications and variations, provided that they are within the scope of the appended claims and their equivalents.

What is claimed is:

1. An image sensor comprising:
a semiconductor substrate having a readout circuitry formed thereon;
an interlayer insulating layer over the semiconductor, the insulating layer including a lower metal line electrically coupled with the readout circuitry;
a buffer insulating layer over the interlayer insulating layer;
a lower electrode penetrating the buffer insulating layer to be connected with the lower metal line;
a crystalline semiconductor layer over the buffer insulating layer, the crystalline semiconductor layer being partially connected with the lower electrode; and
a photodiode in the crystalline semiconductor layer.

2. The image sensor of claim 1, wherein the lower electrode comprises:
an electrode section connected with the lower metal line and having a first width; and
a via contact extending upward from the electrode section and having a second width narrower than the first width, at least a portion of the via contact extending into the crystalline semiconductor layer.

3. The image sensor of claim 1, wherein the photodiode comprises a first conductive region formed in a first region of the crystalline semiconductor layer and a second conductive region formed in a second region of the crystalline semiconductor layer, the first region being deeper than the second region.

4. The image sensor of claim 3, wherein the lower electrode is partially connected with the first conductive region.

5. The image sensor of claim 1, wherein the readout circuitry comprises:
an electrical junction region formed in the semiconductor substrate, and the electrical junction region comprises:
a first conductive type ion implantation region formed in the semiconductor substrate; and
a second conductive type ion implantation region formed over the first conductive type ion implantation region.

6. The image sensor of claim 5, further comprising:
a first conductive type connection region over the electrical junction region, the first conductive type connection region being electrically connected with the lower metal line.

7. The image sensor of claim 5, wherein the electrical junction region comprises a PNP junction.

8. The image sensor of claim 1, wherein the readout circuitry has a potential difference between a source and a drain of a transistor.

9. The image sensor of claim 8, wherein the transistor is a transfer transistor, and the source of the transfer transistor has an ion implantation concentration lower than that of a floating diffusion region.

10. The image sensor of claim 5, further comprising:
a first conductive type connection region formed at one side of the electrical junction region and electrically coupled with the lower metal line.

11. The image sensor of claim 10, wherein the first conductive type connection region contacts a device isolation region and is connected with the electrical junction region.

12. A method for manufacturing an image sensor comprising:
forming a readout circuitry on a semiconductor substrate;
forming an interlayer insulating layer including a lower metal line over the semiconductor substrate such that the lower metal line is electrically coupled with the readout circuitry;
forming a crystalline semiconductor layer over a carrier substrate;
forming a buffer insulating layer over the crystalline semiconductor layer;
forming a photodiode in the crystalline semiconductor layer;
forming a lower electrode penetrating the buffer insulating layer and configured to be connected with the photodiode;
bonding the interlayer insulating layer to the buffer insulating layer such that the lower metal line is electrically coupled with the lower electrode; and
removing the carrier substrate such that the photodiode on the semiconductor substrate is exposed,
wherein the lower electrode comprises an electrode section having a first width, and a via contact extending from the electrode section and having a second width narrower than the first width, at least a portion of the via contact extending into the crystalline semiconductor layer, and the electrode section being electrically coupled with the lower metal line

13. The method of claim 12, wherein the forming of the lower electrode comprises:
forming a trench in the buffer insulating layer;
forming a via hole extending in a downward direction of the trench; and
depositing a conductive material in the trench and the via hole to form the electrode section in the trench and form the via contact in the via hole.

14. The method of claim 12, wherein the forming of the photodiode comprises:
forming a first conductive region in the crystalline semiconductor layer corresponding to a lower portion of the buffer insulating layer; and
forming a second conductive region under the first conductive region.

15. The method of claim 14, wherein the via contact is connected with the first conductive region.

16. The method of claim 12, wherein the forming of the readout circuitry comprises:
forming an electrical junction region in the semiconductor substrate, comprising:
forming a first conductive type ion implantation region in the semiconductor substrate; and
forming a second ion implantation region on the first conductive type ion implantation region.

17. The method of claim 16, further comprising:
forming a first conductive connection region electrically coupled with the lower metal line.

18. The method of claim 17, wherein the forming of the first conductive type connection region is performed after a contact etch for the lower metal line is performed.

19. The method of claim 16, further comprising:
forming a first conductive connection region electrically coupled with the lower metal line at one side of the electrical junction region.

20. The method of claim 19, wherein the first conductive type connection region is formed to contact a device isolation region and be electrically coupled with the electrical junction region.
